(19) United States
(12) Patent Application Publication
(10) Pub. No.: US 2009/0255575 A1
(43) Pub. Date: Oct. 15, 2009

(54) LIGHTWEIGHT SOLAR CELL

(76) Inventor: Michael Tischler, Phoenix, AZ (US)

Correspondence Address: FOLEY & LARDNER LLP, P.O. BOX 80278, SAN DIEGO, CA, 92138-0278, US

(21) Appl. No.: 12/417,569

(22) Filed: Apr. 2, 2009

Related U.S. Application Data
(60) Provisional application No. 61/042,504, filed on Apr. 4, 2008.

(51) Int. Cl. H01L 31/00

(52) U.S. Cl. 136/255; 136/256

(57) ABSTRACT

Lightweight solar cells include a multiple-bandgap material.

### CROSS-REFERENCE TO RELATED APPLICATION

This patent application claims priority to U.S. Provisional Patent Application No. 61/042,504, entitled “LIGHTWEIGHT SOLAR CELL,” filed Apr. 4, 2008, which is hereby incorporated by reference in its entirety for all purposes.

### BACKGROUND OF THE INVENTION

This application relates generally to solar cells. More specifically, this application relates to the production and use of lightweight solar cells.

There are certain applications for solar cells that raise issues in addition to those issues that exist generally for solar cells. For example, solar cells for space applications have a number of constraints that are not present for terrestrial solar cells. One such constraint is the weight of the solar cell because of the high cost of launching anything into space. A great deal of effort is made generally to reduce the weight of any object carried on space vehicles, including the weight of solar cells. While the solar cells may appear not to contribute significantly to the total weight of the spacecraft, the large area and relatively high density of semiconductors does make this weight impact significant. The main technique used to reduce the weight of a solar cell is to use a very thin substrate on which the solar cell is fabricated so that the structure is almost entirely made up of the electrically and optically active solar cell, with as little substrate weight as possible.

It is also desirable for space solar cells to have high efficiency. To that end, solar cell structures have evolved in recent years to become more sophisticated, particularly by using a multijunction solar-cell structure. In such a structure, multiple solar cells with different absorption bands are stacked on top of each other. A typical triple-junction solar cell may, for example, have a thickness in the range of about 10 μm. While these types of solar cells are relatively thick, their higher efficiency permits the use of a smaller array for a required power. However, as space applications become more advanced, the power requirements also increase, so that there is a need for high-efficiency lightweight solar cells.

This application discloses solar cells with high efficiency and lighter weight than such multijunction solar cells.

### BRIEF SUMMARY OF THE INVENTION

Embodiments of the invention provide a lightweight solar cell that comprises a multiple-bandgap material. The material may comprise a doped material. In some embodiments, the solar cell is disposed over a substrate having a thickness less than 1 μm. The solar cell may be integrated with an object or with a device that is powered by energy generated with the solar cell. For example, in one embodiment, a spacecraft is provided that comprises a solar cell having a multiple-bandgap material.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components.

FIG. 1 provides a schematic illustration of a solar-cell structure that may be produced in accordance with embodiments of the invention;

FIGS. 2A-2C illustrate the electronic structure of different types of monocrystalline solar cells; and

FIG. 3 is a flow diagram summarizing methods of generating energy using lightweight multiband solar cells.

### DETAILED DESCRIPTION OF THE INVENTION

Embodiments of the invention provide lightweight solar cells that make use of multiband material. The use of such material reduces the overall weight of the solar cells by virtue of providing collection of an increased portion of the solar spectrum in a cell that is relatively thinner than conventional cells, and makes them especially suitable for space and other specialized applications where weight is of concern.

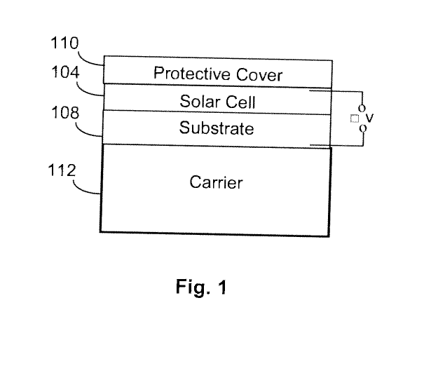

A general overview of the structure of a device that may be made in accordance with embodiments of the invention is provided with FIG. 1. The structure is formed around a substrate 108 that is disposed over a carrier 112, with the solar cell 104 and a protective cover 106 being formed over the substrate 108. This particular structure is shown merely for exemplary purposes and is not intended to be limiting; in various alternative embodiments, different portions of this structure might be omitted, with some embodiments having only the solar cell 104, others having the solar cell 104 and substrate 108, and others having no protective cover 106. In still other embodiments, a variety of other structures might additionally be included. Whatever the particular structure, the solar cell 104 itself comprises a multiband material.

There are a number of different substrates 108 that may be used in different embodiments, including elemental or binary group-IV substrates made of silicon, germanium, or SiC; III-V compounds such as GaAs, GaP, AlAs, AlP, InGaAs, and InGaP; IV-VI compounds such as ZnSe; and other substrate materials such as sapphire.

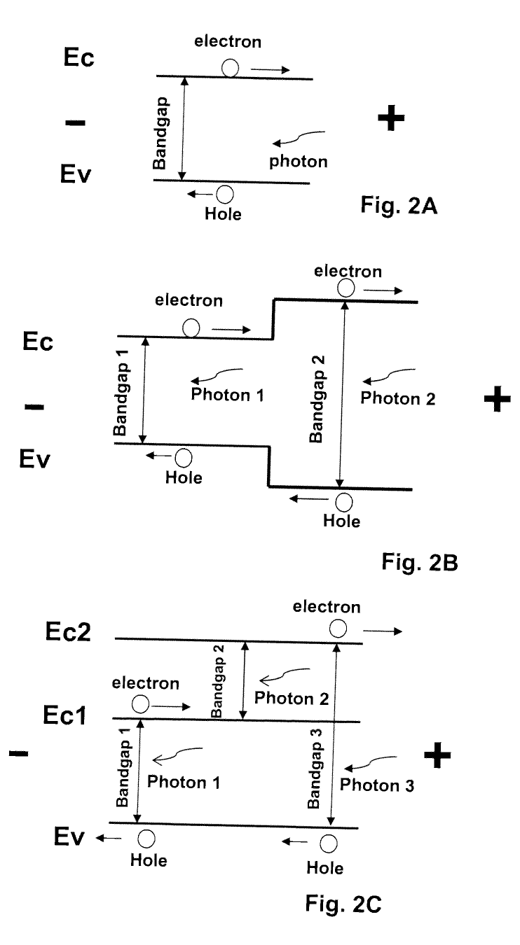

The solar cell 104 comprises a multiband material. FIGS. 2A-2C provide illustrations of different electronic structures to illustrate the particular characteristics of multiband material. The simplest structure, illustrated in FIG. 2A, makes use of a single junction. Specifically, a single bandgap material is used to capture a portion of the incident light spectrum, with photons that have an energy greater than the bandgap of the material being absorbed to create an electron-hole pair that produces a DC current under the action of an electric field. The conversion efficiency for a single-junction cell has a peak near the bandgap of the active region and decreases rapidly for higher energies. Using a single bandgap to convert a substantial portion of the solar spectrum is therefore relatively inefficient, with a theoretical maximum efficiency of 35% but with typical efficiencies actually using this technology being on the order of 15-20%.

Conversion of the available solar spectrum to electrical energy is improved when multiple junctions are used. This can be accomplished by engineering multiple bandgaps into a single cell. This is illustrated schematically with FIG. 2B, in which individual cells with different bandgaps are grown monolithically on top of one another with the largest bandgap material located at the top of the stack. With this approach, a larger portion of the incident energy is able to be absorbed, thereby increasing the total efficiency of the cell. The most popular approach to multijunction cells currently being researched are based on lattice-matched GaInP/GaAs double-junction cells and GaInP/GaAs/Ge triple junction cells and achieve maximum efficiencies on the order of 30-35% in practice. The theoretical maximum efficiency for the use of two-junction cells is 50% and the theoretical maximum efficiency for the use of three-junction cells is 56%.

Embodiments of the invention make use of a multiple-band technique in which the number of bandgaps within a single cell is increased without the use of multiple materials. Introduction of a small fraction of highly electronegative atoms into a host semiconductor material dramatically alters the electronic band structure of the host material by splitting the conduction band into two sub-bands. Because of the interaction between the two subbands, one subband is pushed to an energy higher than that of the bandgap of the host semiconductor and the other subband is pushed to a lower energy. This results in the creation of an additional energy level in the base structure to provide for three optical transitions as shown in FIG. 2C. The structure is therefore functionally equivalent to a triple-junction cell. The theoretical maximum efficiency using this approach is approximately 63%. The inclusion of still additional bands using this technique promises even higher efficiencies, with four-band approaches providing a theoretical maximum efficiency of 72%.

The use of multiband material in a solar cell allows the structure to absorb and use a wide range of the solar spectrum, with a number of notable features. These include reduced complexity of design, growth, and fabrication, higher yield, and reduced cost. The reduced cost results directly from the ability to grow a much simpler and thinner structure, and results indirectly from the simplified structure and processing that achieves a higher yield. In some embodiments, the lightweight solar cell so produced is deployed on a spacecraft. In certain embodiments, the substrate over which such a solar cell is formed is also thin, having a thickness in some embodiments less than 2 μm, less than 1 μm, less than 0.5 μm, less than 0.2 μm, or less than 0.1 μm. Alternatively, the solar cell may be removed entirely from the substrate on which it is formed, such as by selective chemical or other mechanisms known to those of skill in the art, and remounted on a separate carrier.

In some embodiments, one or more of the solar cells comprises a dilute nitride absorbing layer and an emitter layer. The dilute nitride absorbing layer may be provided as a ternary, quaternary, quinary, or higher alloy. But in addition to including at least one group-III element and at least one group-V element, the absorbing layer in these embodiments includes nitrogen. Examples of group-III elements that may be used comprise Ga, In, and Al, among others, and examples of group-V elements that may be used comprise As, P, Sb, and S, among others. Thus, the absorbing layer comprises a material with the general formula GaₓIn_{y}Al_{z}NₐAs_{b}P_{c}Sb_{d}Sₑ, where x<1, y<1, z<1, 0.0001<a<0.1, b<1, c<1, d<1, and e<1. An exemplary range for a concentration of the nitrogen in the absorbing layer is 0.01-5.0 at. %, for example 0.1-5.0 at. %. The electrically active carrier concentration in illustrative embodiments is between 10¹⁶ and 5×10¹⁸ cm⁻³, such as between 5×10¹⁶ and 5×10¹⁸ cm⁻¹. The absorbing layer functions by absorbing photons to create electron-hole pairs. Further discussion of this absorption mechanism is described in greater detail below. A suitable thickness for the absorbing layer in different embodiments is within the range of 0.1-10.0 μm.

In some embodiments, the multiple-bandgap material comprises doped or undoped SiC, GaN, GaP, GaS, AlAs, AlP, CdS, ZnTe, ZnSe, ZnS, or an alloy thereof. These materials may be doped, for example with about 0.01% to about 10% N.

The emitter may be doped using carriers of the opposite charge to those used in the absorbing layer. For example, in those embodiments where the absorbing layer is n-type doped, the emitter may be p-type doped. In one such group of examples, the emitter may have an electrically active carrier concentration in the range 10¹⁷-10²⁰ cm⁻³. The emitter layer may advantageously have a larger bandgap than the absorbing layer, thereby minimizing surface recombination as described further below. Examples of materials that may be used for a p-type emitter layer include GaP, AlAs, AlInP, AlPAs, AlInAsP, InGaP, and ZnSe, among others. A suitable thickness of the emitter layer is between 0.05 and 1.0 μm.

There are a number of other general considerations relevant to specific compositions in the solar-cell structure. For example, consider the case where the dilute nitride absorbing layer comprises GaNₓAs_{y}P_{1-x-y}. For such a material system to exhibit multiband properties, x and y should be selected so that there is sufficient incorporation of active nitrogen to separate the conduction band from the intermediate band. This may be achieved in embodiments of the invention with 0.01%<x>10%, such as x>0.01. At the same time, the phosphorus concentration may be selected to provide a direct Γ bandgap that is less than the indirect X bandgap. This is achieved in specific embodiments with 0.35<(1−x−y)<0.50. In particular embodiments, 0.005≦x≦0.050 and 0.3≦y≦0.7. Additionally, the compositions within this range may be selected to achieve relatively higher carrier mobility in the Ec2 conduction band, and minimize the conduction-band discontinuities, enhancing transport through the device.

For purposes of illustrating the effect of using multiband material in the solar cell, consider a solar cell made with a semiconductor thickness of 10 μm. The volume of semiconductor material in 1 m² of a solar-cell array is about 10 grams. The largest solar-cell array in space is that deployed on the International Space Station and has an area of 830 m². Using this area and the density of GaAs (5.3 g/cm³) as the average density in a solar-cell structure, the weight of the semiconductor material in this solar cell is about 44 kg. It currently costs approximately $10,000 to launch a pound into space using the space shuttle, so the cost of launching this area of solar cells is about $1,000,000. When multiband material is used in accordance with embodiments of the invention, the thickness of the solar cell can be reduced to one half or one third of that of a multi-junction solar cell, thus creating a launch savings in the range of 50-75%. For the example discussed here, that would be a savings of $500,000-700,000.

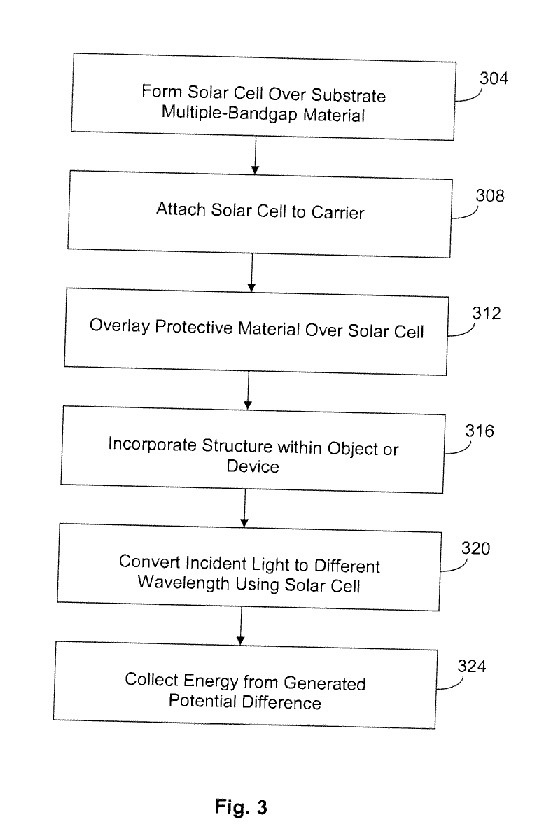

A general overview of methods of the invention is accordingly provided with the flow diagram of FIG. 3. At block 304, a solar cell is formed over a substrate using multiple-bandgap material. The formation of the solar cell may be performed in a number of different ways, one example being the use of an epitaxial-growth process that uses chemical-vapor deposition or other growth techniques. In alternative embodiments, a previously formed solar cell may be bonded or otherwise attached to the substrate. At block 308, the combined solar cell and substrate is attached to the carrier and a protective cover or other protective material is overlaid at block 312.

The resulting structure may be incorporated within an object or device at block 316. As previously noted, in specific embodiments the structure is included on a spacecraft, although such an example is not intended to be limiting and the structure may be incorporated with other objects or devices that find utility with a lightweight solar cell.

Whatever the specific characteristics, the light incident on the solar cell is converted to a potential difference at block 320 so that energy may be collected from the potential difference at block 324. Energy collected by this conversion process may subsequently be used directly in powering the device to which the solar cell is attached, or by storing it chemically in a battery or in another form in some other energy-storage device. For instance, a spacecraft that includes the solar cell may be powered by energy generated from light incident on the solar cell.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A solar cell comprising a multiple-bandgap material.

2. The solar cell recited in claim 1 wherein the material comprises a doped material.

3. The solar cell recited in claim 1 wherein the solar cell is disposed over a substrate having a thickness less than 1 μm.

4. The solar cell recited in claim 1 comprising a substrate over which the multiple-bandgap material is formed, wherein the substrate comprises GaP, sapphire, or SiC.

5. The solar cell recited in claim 1 wherein the multiple-bandgap material has an efficiency similar to that of a multifunction solar cell and a total thickness in the range of about half of that of the multifunction solar cell or less than half of that of the multifunction solar cell.

6. The solar cell recited in claim 5 wherein the multiple-bandgap material comprises SiC, GaN, GaP, GaS, AlAs, AlP, CdS, ZnTe, ZnSe, ZnS, or an alloy thereof.

7. The solar cell recited in claim 6 wherein the multiple-bandgap material comprises N in a concentration between about 0.01% and about 10%.

8. The solar cell recited in claim 1 wherein the multiple-bandgap material comprises an absorbing layer and an emitter layer.

9. The solar cell recited in claim 8 wherein the multiple-bandgap material comprises a dilute nitride absorbing layer having a semiconducting alloy with a group-III element, a group-V element, and nitrogen.

10. The solar cell recited in claim 9 wherein the dilute nitride absorbing layer comprises a nitrogen concentration between 0.01 at. % and 5.0 at. %.

11. The solar cell recited in claim 9 wherein the dilute nitride absorbing layer has an electrically active carrier concentration between 10¹⁶ and 5×10¹⁸ cm⁻³.

12. The solar cell recited in claim 9 wherein the dilute nitride absorbing layer has an electrically active carrier concentration between 5×10¹⁶ and 5×10¹⁸ cm⁻³.

13. The solar cell recited in claim 1 wherein:
the multiple-bandgap material comprises GAₓIn_{y}Al_{z}NₐAs_{b}P_{c}Sb_{d}Sₑ;
x<1;
y<1;
z<1;
0.0001≦a≦0.1;
b<1;
c<1;
d<1; and
e<1.

14. The solar cell recited in claim 1 wherein:
the multiple-bandgap material comprises Ga, As, N, and P; and
the N has a concentration in the range of about 0.01% to about 10%.

15. The solar cell recited in claim 1 wherein the solar cell is formed over a substrate comprising GaP, sapphire, or silicon carbide.

16. An object comprising the solar cell recited in claim 1.

17. A device comprising the solar cell recited in claim 1 and powered by energy generated with the solar cell recited in claim 1.

18. A spacecraft comprising a solar cell, wherein the solar cell comprises a multiple-bandgap material.
